(19) United States
(12) Patent Application Publication
(10) Pub. No.: US 2016/0023120 A1
(43) Pub. Date: Jan. 28, 2016

(54) Game Machine Controller Method and PCB

(71) Applicants: Gary Balaban, Old Bridge, NJ (US); John Maurer, Whitehouse Stations, NJ (US)

(72) Inventors: Gary Balaban, Old Bridge, NJ (US); John Maurer, Whitehouse Stations, NJ (US)

(21) Appl. No.: 14/853,937

(22) Filed: Sep. 14, 2015

Related U.S. Application Data
(63) Continuation-in-part of application No. 13/849,500, filed on Mar. 23, 2013, now abandoned.
(60) Provisional application No. 61/614,706, filed on Mar. 23, 2012.

(51) Int. Cl. A63F 13/77; A63F 13/235; H05K 1/18

(52) U.S. Cl. CPC A63F 13/77; H05K 1/18; A63F 13/235

(57) ABSTRACT

A printed circuit board (PCB) installed on any game machine providing two wires for each meter a user desired to monitor in the machine, and two wires to supply power to the PCB. A monitor attached to any meter ranging from 12 volts to 48 volts that is not polarity specific. The PCB connected via Wifi, regular CAT 5 Internet cable or even via cellular service for areas where the Internet is not available. A single “HUB” per location can provide access and monitoring for a plurality of machines located at one location. The controller can transmit negative and positive alerts provide the user. Additionally, a user can set “alarms” for each item they are monitoring. Using the controller of the present invention, game machines are all wirelessly connected to the game machine comprised of the HUB and can be moved anywhere in the location.

### CROSS REFERENCE TO RELATED APPLICATIONS

This application is a continuation in part (CIP) and claims priority from U.S. patent application Ser. No. 13/849,500, entitled “Game Machine Controller Method and PCB”, filed on 23 Mar. 2013. The benefit under 35 USC §119(e) of the United States provisional application is hereby claimed, and the aforementioned application is hereby incorporated herein by reference.

U.S. patent application Ser. No. 13/849,500 application claims priority from U.S. Patent Application Ser. No. 61/614,706, entitled “Game Machine Controller Method and PCB”, filed on 23 Mar. 2012. The benefit under 35 USC §119e of the United States provisional application is hereby claimed, and the aforementioned application is hereby incorporated herein by reference.

### FEDERALLY SPONSORED RESEARCH

Not Applicable

### SEQUENCE LISTING OR PROGRAM

Not Applicable

### TECHNICAL FIELD OF THE INVENTION

The present invention relates generally to game machines. More specifically, the present invention relates to game machines featuring an electronic circuit board controller to provide remote, wireless, machine monitoring.

### BACKGROUND OF THE INVENTION

Many game machines are known in the prior art. In the current state of the prior art the owner of a machine must manually check the gameplay, function and payout of each machine in person. Machine operators may have many machines spread across multiple locations, which makes physically checking machines on a period basis an expensive and time consuming process.

What is needed is a controller that provides remote, wireless monitoring of one or more games that can be installed on older machines without the need for retro-fitting or re-wiring that can provide alarms or other notices to the owner of the machines in the event of coin jams, low product or tickets, bill accepting or jamming issues, and revenue tracking.

### SUMMARY OF THE INVENTION

The present invention is a printed circuit board (PCB) that can be easily and quickly installed on any game machine. The installation consists of two wire for each meter a user desired to monitor in the machine, and two wires to supply power to the PCB. A monitor can be attached to any meter ranging from 12 volts to 48 volts and it is not polarity specific so it can not be attached or installed incorrectly.

The PCB connect via WIFI, regular CAT 5 Internet cable or even via cellular service for areas where the Internet is not available. A single “HUB” per location can provide access and monitoring for a plurality of machines located at one location. Using the controller of the present invention, game machines are all wirelessly connected to the game machine comprised of the HUB and can be moved anywhere in the location. Currently, each game can be up to 300 feet from each other. Each game will automatically “join” the network and be automatically recognized by the HUB so there is no need for any programming on a per machine basis.

The controller can transmit negative and positive alerts provide the user or owner with a positive alert to positive events such as coin box full, bill box full, and X amount of toy/prizes given away. Negative alerts provide a user or owner notice of negative events such as tickets stuck and not being given out, coins not put in the machine in a certain amount of time (say 6 pm-10 pm on a Saturday night.) and many other variables based on time or a specific number.

Additionally, a user can set “alarms” for each item they are monitoring such as when tickets are low, prizes are low, too many coins are in the cash box, too many bills are in the bill box, etc. A user can also can set timer alarms to see if a game is making money during a certain time. A timer alarm checks for coin jambs or ticket jambs as well.

### BRIEF DESCRIPTION OF THE DRAWINGS

The accompanying drawings, which are incorporated herein an form a part of the specification, illustrate the present invention and, together with the description, further serve to explain the principles of the invention and to enable a person skilled in the pertinent art to make and use the invention.

FIG. 1 illustrates the PCB of the present invention;

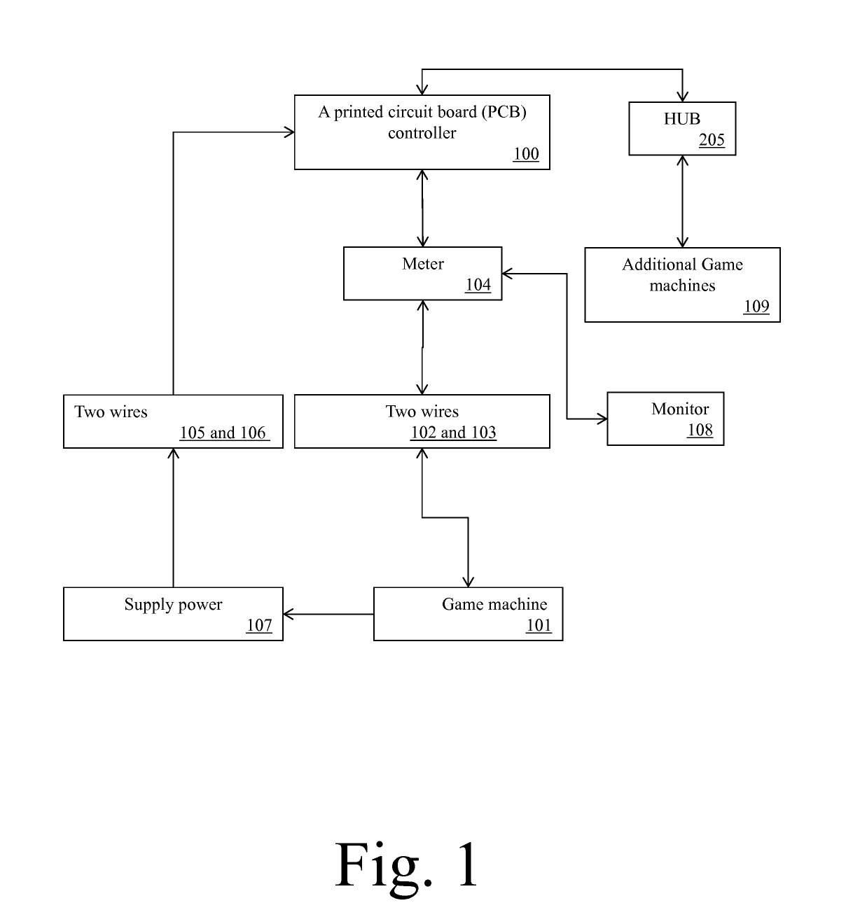

FIG. 2 is an overview of the layout and connectivity of the game machines using the PCB controller and method of the present invention; and

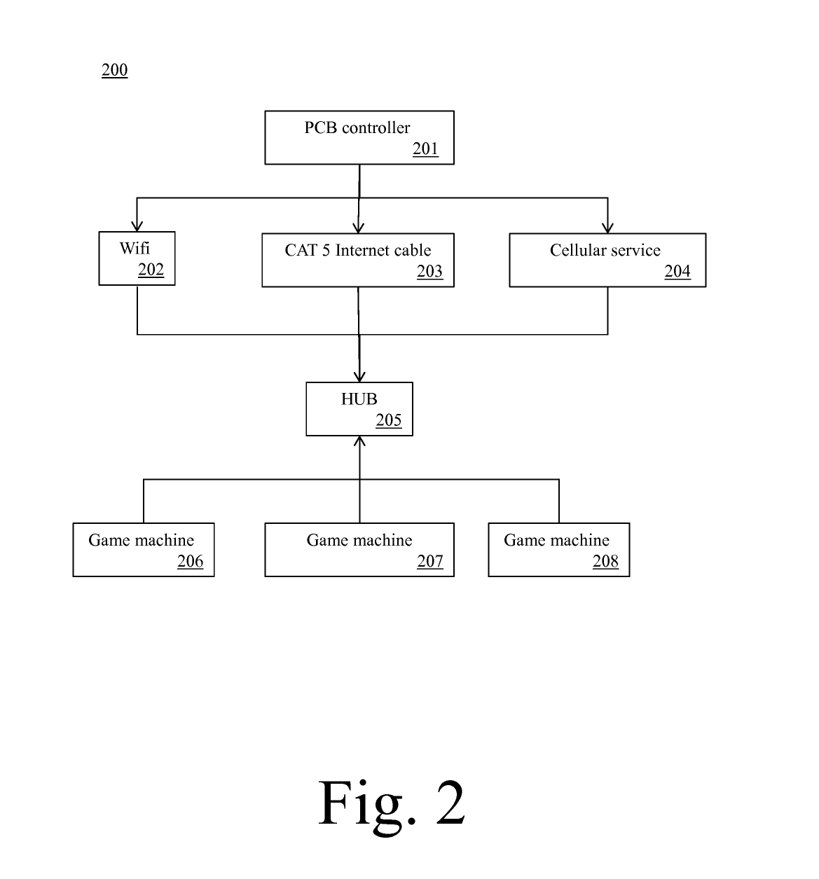

FIG. 3 is a flow chart illustrating the method and process executed by the PCB controller.

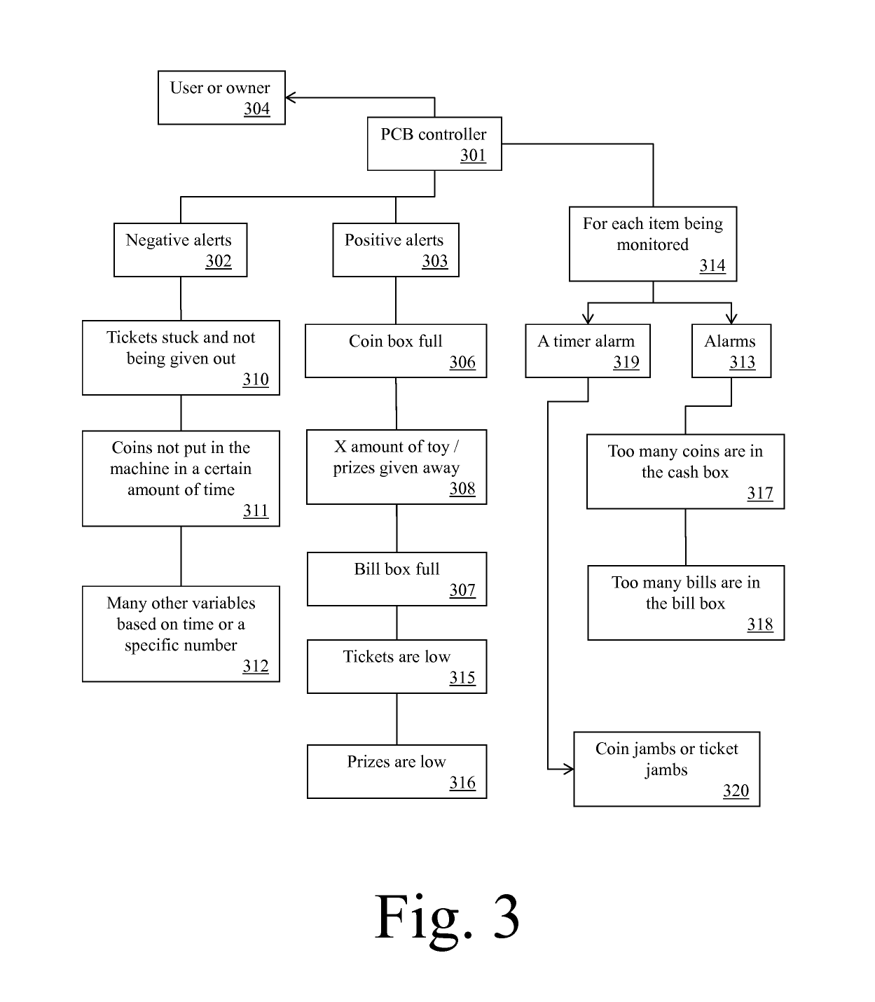

### DETAILED DESCRIPTION OF THE INVENTION

In the following detailed description of the invention of exemplary embodiments of the invention, reference is made to the accompanying drawings (where like numbers represent like elements), which form a part hereof, and in which is shown by way of illustration specific exemplary embodiments in which the invention may be practiced. These embodiments are described in sufficient detail to enable those skilled in the art to practice the invention, but other embodiments may be utilized and logical, mechanical, electrical, and other changes may be made without departing from the scope of the present invention. The following detailed description is, therefore, not to be taken in a limiting sense, and the scope of the present invention is defined only by the appended claims.

In the following description, numerous specific details are set forth to provide a thorough understanding of the invention. However, it is understood that the invention may be practiced without these specific details. In other instances, well-known structures and techniques known to one of ordinary skill in the art have not been shown in detail in order not to obscure the invention. Referring to the figures, it is possible to see the various major elements constituting the apparatus of the present invention.

Now referring to the Figures, an embodiment of the PCB controller is shown. The present invention is a printed circuit board (PCB) controller 100 that can be easily and quickly installed on any game machine 101. The installation consists of two wires 102 and 103 for each meter 104 a user desires to monitor in the game machine 101, additionally, two wires 105 and 106 to supply power 107 to the PCB controller 100. A monitor 108 can be attached to any meter 104 ranging from 12 volts to 48 volts and it is not polarity specific so it can not be attached or installed incorrectly.

The PCB controller 201 connects via Wifi 202, regular CAT 5 Internet cable 203, or even via cellular service 204 for areas where the Internet is not available. A single “HUB” 205 per location 200 can provide access and monitoring for a plurality of machines 206, 207, and 208 located at one location 200.

The PCB controller 301 can transmit negative alerts 302 and positive alerts 303 to the user or owner 304 with a positive alert 303 to positive events 305 such as coin box full 306, bill box full 307, and X amount of toy/prizes given away 308. Negative alerts 303 provide a user or owner notice of negative events 309 such as tickets stuck and not being given out 310, coins not put in the machine in a certain amount of time 311, and many other variables based on time or a specific number 312.

Additionally, a user can set “alarms” 313 for each item 314 they are monitoring such as when tickets are low 315, prizes are low 316, too many coins are in the cash box 317, too many bills are in the bill box 318, etc. A user can also set timer alarms 319 to see if a game is making money during or over a certain period of time. A timer alarm 319 checks for coin jambs or ticket jambs 320 as well.

Using the PCB controller 100 of the present invention, a plurality of game machines 109 are all wirelessly connected to the game machine further comprised of the HUB 205 and can be moved anywhere in the location. Currently, each game can be up to 300 feet from each other. Each game will automatically “join” the network and be automatically recognized by the HUB 205 so there is no need for any programming on a per machine basis.

Thus, it is appreciated that the optimum dimensional relationships for the parts of the invention, to include variation in size, materials, shape, form, function, and manner of operation, assembly and use, are deemed readily apparent and obvious to one of ordinary skill in the art, and all equivalent relationships to those illustrated in the drawings and described in the above description are intended to be encompassed by the present invention.

Furthermore, other areas of art may benefit from this method and adjustments to the design are anticipated. Thus, the scope of the invention should be determined by the appended claims and their legal equivalents, rather than by the examples given.

The embodiments of the invention in which an exclusive property or privilege is claimed are defined as follows:

1. A method for monitoring a game machine comprising:
providing a PCB with a memory;
equipping the PCB with a wireless access point to allow the owner to remotely to access and monitor functions;
retrieving information from the PCB memory;
performing diagnostics of the game machine via the PCB;
setting monitoring conditions; and
setting conditions for sending alerts.

2. The method of claim 1 further comprising:
a plurality of game machines in a single location provided with the PCB;
one of the plurality of game machines comprised of a PCB with a wireless access point to allow the owner to remotely to access and monitor functions; and
remaining game machines wirelessly networked to the game machine with the wireless access point.

3. The method of claim 2 further comprising:
providing a remote access point to the controller via the Internet, Wifi, or Cellular network on the game machines comprised of a PCB with a wireless access point; and
providing a remote access point to a plurality of game machines via a local area wireless network.

4. The method of claim 3, wherein access is provided by any mobile electronic device with an Internet connection.

5. A printed circuit board for installation in a game machine comprising:
one or more monitors;
two wires for each provided meter used to monitor a function in the game machine;
two wires to supply power to the printed circuit board;
Wifi, CAT 5 Internet Cable, or cellular service connection to a remote network.

6. The printed circuit board of claim 5, wherein a monitor can be attached to any meter ranging from 12 volts to 48 volts.

7. The printed circuit board of claim 5, wherein the two wires for each monitor are non-specific polarity.

8. The printed circuit board of claim 5, further comprising
a single HUB per location providing access and monitoring for a plurality of machines located at one location.

9. The printed circuit board of claim 5, wherein
the controller can transmit negative and positive alerts;
provide a positive alert to positive;
provide negative alerts to negative events.

10. The printed circuit board of claim 5, further comprising one or more alarms for each item being monitored.

11. The printed circuit board of claim 5, further comprising
setting a timer alarm to see if a game is making money during a certain period of time; and
the timer alarm checks for coin jambs or ticket jambs.
